(19) United States
(12) Patent Application Publication
(10) Pub. No.: US 2012/0028808 A1
(43) Pub. Date: Feb. 2, 2012

(54) SUPERCONDUCTOR SUPERIOR IN DEPENDENCY OF CRITICAL CURRENT DENSITY ON MAGNETIC FIELD ANGLE

(76) Inventors: Kenji Kaneko, Fukuoka-shi (JP); Teruo Matsushita, Kitakyushu-shi (JP); Akira Ibi, Koto-ku (JP); Masateru Yoshizumi, Koto-ku (JP); Teruo Izumi, Koto-ku (JP); Yuh Shiohara, Koto-ku (JP)

(21) Appl. No.: 13/111,063

(22) Filed: May 19, 2011

(30) Foreign Application Priority Data
Jul. 30, 2010 (JP) 2010-172400

(51) Int. Cl. H01L 39/12; H01L 39/08

(52) U.S. Cl. 505/230; 174/125.1

(57) ABSTRACT

An oxide superconducting tape comprised of a substrate on which a GdBa₂Cu₃O_{7-δ} (δ=0 to 1) superconductor layer is formed, characterized in that,

inside of said superconductor layer, columnar or rod-shaped BaZrO₃ crystals are dispersed such that they are inclined from c-axis of the superconducting crystals and that BaZrO₃ crystals adjacent in longitudinal directions are in a skew position.

### TECHNICAL FIELD

The present invention relates to a superconductor comprised of a type II superconductor inside of which ordinary conducting particles are dispersed, more particularly relates to a superconductor with a high critical current density and with a small magnetic field angle dependency.

### BACKGROUND ART

Various studies have been made on a superconductor film comprised of a type II superconductor, that is, an oxide superconductor film, in which a plurality of columnar or rod-shaped crystals extending in a film thickness direction and comprised of an ordinary conducting substance, called “nanorods”, are dispersed and in which these nanorods are used as pinning centers.

It is known that such a superconductor film has a high critical current density due to nanorods which are formed internally acting as effective pinning centers.

PLT 1 discloses, as a superconductor film with a high critical current density and a small magnetic field angle dependency, a structure comprised of a superconductor layer of a superconducting substance expressed by REBa₂Cu₃Oₓ in which columnar crystals comprised of an ordinary conducting substance containing Ba and arranged intermittently in the film thickness direction are formed.

However, progress is being made in development of superconductive magnetic energy storage (SMES), cables, transformers, etc., using superconducting tape. Further improvements in properties are being required from such applications. The conventional magnetic field angle dependency has been insufficient.

### CITATION LIST

### Patent Literature

PLT 1: Japanese Patent Publication (A) No. 2008-130291

### SUMMARY OF INVENTION

### Technical Problem

The present invention was made in view of the above situation and has as its object the provision of a superconductor with superior dependency of the critical current density on the magnetic field angle compared with the past.

### Solution to Problem

The inventors worked to solve the above problem by intensively studying of nanorod arrangement in a superconductor. As a result, they discovered that by making the nanorods slant in the superconductor and by further making adjacent nanorods be in a skew position, the dependency on the magnetic field angle is improved.

The present invention was made based on the above discovery and has as its gist the following.

(1) An oxide superconducting tape comprised of a substrate on which a GdBa₂Cu₃O_{7-δ} (δ=0 to 1) superconductor layer is formed, characterized in that, inside of said superconductor layer, columnar or rod-shaped BaZrO₃ crystals are dispersed such that they are inclined from c-axis of the superconducting crystals and that BaZrO₃ crystals adjacent in longitudinal directions are in a skew position.

### Advantageous Effect of Invention

According to the present invention, it is possible to obtain a previously nonexistent superconductor with little dependency of the critical current density on the magnetic field.

### BRIEF DESCRIPTION OF DRAWINGS

FIG. 1 is a view showing schematically the constitution of a superconductor film of the present invention.

FIG. 2 is a view showing the relationship between a critical current density and an applied magnetic field angle, wherein (a) shows the case of pure GdBa₂Cu₃O_{7-δ}, and (b) shows the case of GdBa₂Cu₃O_{7-δ} formed with nanorods of BaZrO₃ .

FIG. 3 is a STEM-LAADF image of a cross-section of a superconductor film of an embodiment of the present invention.

FIG. 4 is a 3D reconstructed image of a STEM-LAADF image of a cross-section of a superconductor film of an embodiment of the present invention.

FIG. 5 is a 1D APCs image prepared from a 3D reconstructed image of an ab plane cross-section of a cross-section of a superconductor film of an embodiment of the present invention.

### DESCRIPTION OF EMBODIMENTS

Below, the present invention will be explained in detail.

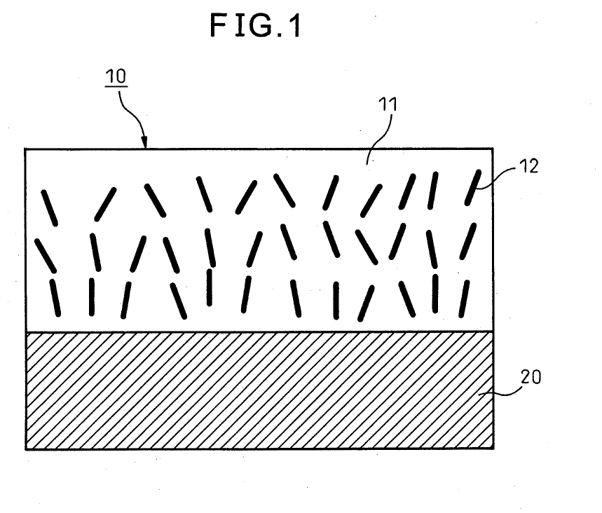

FIG. 1 is a view schematically showing a superconductor film of an oxide superconducting tape according to the present invention. A superconductor film 10 is formed on a substrate 20. Inside a superconductor layer 11 comprised of GdBa₂Cu₃O_{7-δ} (δ=0 to 1), a plurality of columnar or rod-shaped BaZrO₃ crystals (nanorods) 12 are dispersed.

BaZrO₃ crystals are inclined from a c-axis (growth direction of GdBa₂Cu₃O_{7-δ}) and are formed such that they generally grow along the c-axis direction. This slant is not particularly defined, but the presence, in a single superconducting crystal, of BaZrO₃ crystals having various slants in a range of 0 to 60° or so is preferable for reducing the magnetic field angle dependency of the critical current density.

Furthermore, BaZrO₃ crystals are dispersed such that BaZrO₃ crystals adjacent in longitudinal directions are in skew position. The torsional angle between BaZrO₃ crystals and adjacent BaZrO₃ crystals are not restricted. It is preferrable that there are various torsional angles between BaZrO₃ crystals and adjacent BaZrO₃ crystals in order to reduce the magnetic field angle dependency of the critical current density.

For the substrate 20, an Ni-based alloy substrate comprised of Ni, Ni—Cr, Ni—W, etc., a Cu-based alloy substrate comprised of Cu, Cu—Ni, etc., an Fe-based alloy substrate comprised of Fe—Si, stainless steel, etc. can be used. Further, a substrate comprised of a metal substrate on which a plurality of biaxially oriented layers comprised of inorganic materials are formed can be used.

The ratio of the superconducting substance of GdBa₂Cu₃O_{7-δ} and the BaZrO₃ forming the nanorods is not particularly limited. Usually, by weight ratio, it is 99.5:0.5 to 95:5 or so.

If the ratio of BaZrO₃ is too small, the effect of improvement of the critical current density in a magnetic field cannot be obtained. Further, in general, as the ratio of the BaZrO₃ becomes larger, the critical temperature, critical current density in the self magnetic field, and other superconducting properties fall. The ratio of the BaZrO₃ is set to the optimal ratio by the film forming conditions at the time of production of the superconductor film or the usage environment of the superconducting tape (temperature, magnetic field, etc.)

The length of the nanorods is not particularly limited. It is usually 1 to 200 nm or so. For the object of the present invention, that is, the improvement of the magnetic field angle dependency of the critical current density, making the rods a short length is effective.

As explained above, by forming nanorods in the superconductor film, it is possible to obtain a superconductor film with a high critical current density and a small magnetic field angle dependency. The mechanism by which the magnetic field angle dependency of the critical current density becomes smaller in a superconductor film in which nanorods are formed is believed to be as follows: By arranging nanorods in various directions, the arranged nanorods function as pinning points of magnetic flux at various angles. As a result, the anisotropy of the magnetic field angle dependency of the critical current density due to the structure is improved.

Next, the method of production of the superconductor film of the present invention will be explained.

The superconductor film of the present invention can be produced, for example, by using the pulsed laser deposition method (PLD method), sputter method, vacuum deposition method, or other known methods.

Specifically, the superconducting substance and the substance forming the nanorods are mixed by a predetermined ratio and sintered to prepare a target. The target is then mounted in a pulsed laser deposition apparatus.

Next, the substrate mounted in the pulsed laser deposition apparatus is heated in a reduced pressure oxygen atmosphere while forming a superconductor layer including nanorods extending in the film direction on the substrate.

The substrate which is used is not particularly limited. A biaxially oriented substrate (PLD—CeO₂/IBAD—Gd₂Zr₂O₇/Ni superalloy), (PLD-CeO₂/LaMnO₃/IBAD—MgO/Gd₂Zr₂O₇/Ni superalloy) substrate, etc. are preferable.

Since a superconductor film is formed as explained above, by increasing the film forming temperature and pulse layer energy density, it is possible to improve the mobility of the adsorbed atoms which reach the substrate and by using a multi-plume method to pseudo lower the pulse laser oscillation frequency (lowering the supersaturation degree at the time of film formation), it is possible to adjust the length and angle of the nanorods.

### Example

A target comprised of GdBa₂Cu₃O₇+ZrO₂ (5 mol %) and GdBa₂Cu₃O₇+BaZrO₃ (5 mol %) mixed together was fabricated and attached to a PLD apparatus.

After this, under conditions of a pulse energy of 500 to 600 mJ (corresponding to 2 to 3 J/cm²), frequency of 177 Hz (4-plume), substrate temperature of 850 to 900° C., and process pressure of 600 mTorr (=80 Pa), the pulsed laser deposition method (PLD method) was used to form a film and prepare a superconductor film.

For the substrate, a biaxially oriented substrate including a Gd₂Zr₂O₇ layer formed by the ion-beam assisted deposition method (IBAD method) (PLD—CeO₂/IBAD—Gd₂Zr₂O₇/Ni superalloy) was used.

The prepared superconductor film was sliced by an FIB apparatus to prepare plate-shaped and pillar-shaped STEM samples. The STEM-CT method was used to analyze the dispersed state of the BZO nanorods.

### Comparative Example

A pure GdBa₂Cu₃O₇ target was fabricated and attached to a PLD apparatus.

After this, under conditions of a pulse energy of 500 to 600 mJ (corresponding to 2 to 3 J/cm²), frequency of 177 Hz (4-plume), substrate temperature of 850 to 900° C., and process pressure of 600 mTorr (=80 Pa), the pulsed laser deposition method (PLD method) was used to form a film and prepare a superconductor film.

For the substrate, a biaxially oriented substrate including a Gd₂Zr₂O₇ layer formed by the ion-beam assisted deposition method (IBAD method) (PLD—CeO₂/IBAD—Gd₂Zr₂O₇/Ni superalloy) was used.

The prepared superconductor film was sliced by an FIB apparatus to prepare plate-shaped and pillar-shaped STEM samples. The STEM-CT method was used to analyze the dispersed state of the BZO nanorods.

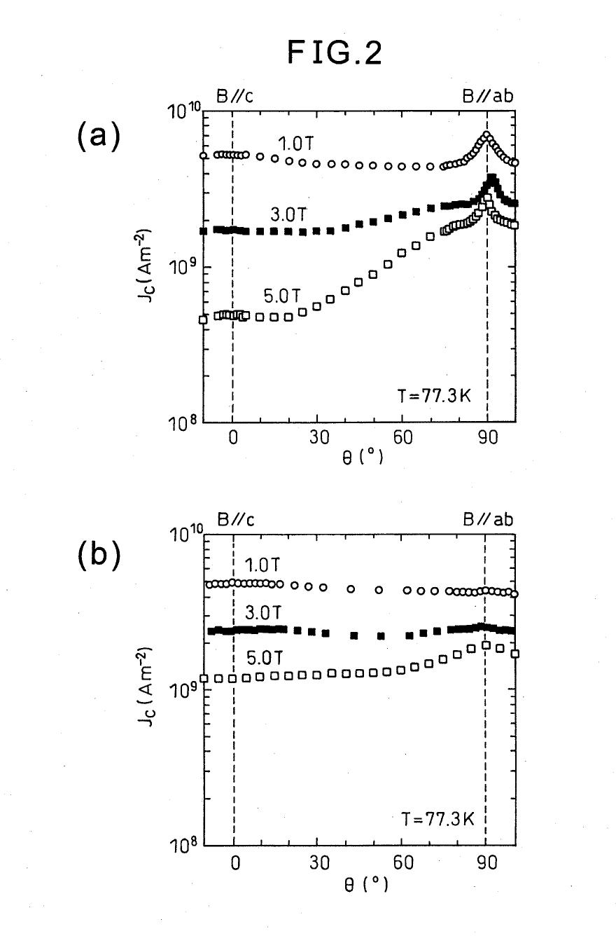

FIG. 2 shows the relationship, at 77.3 K, of the critical current density and the incident angle of the applied magnetic field. (a) shows the results of the above comparative example, while (b) shows the results of the above embodiment. It was learned that the superconductor film of the present invention has an extremely small magnetic field angle dependency of the critical current density.

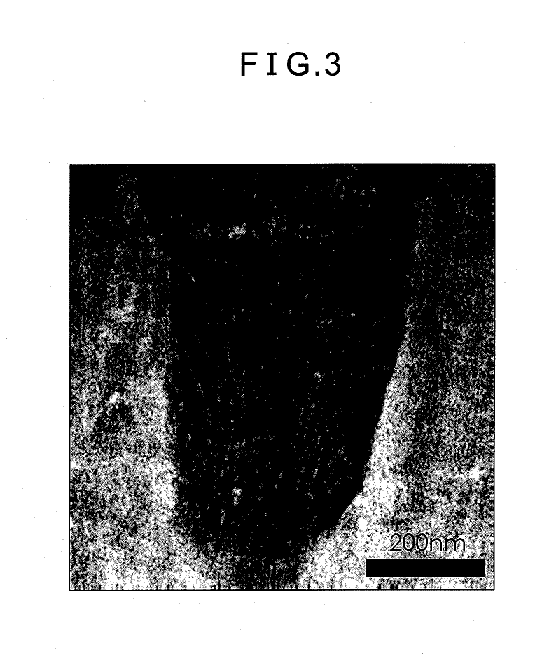

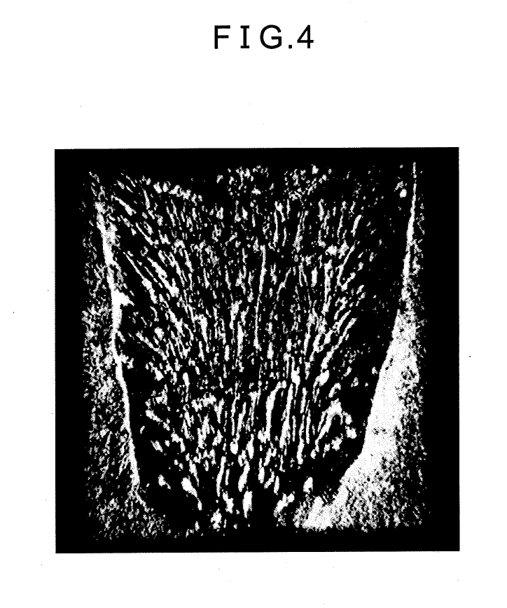

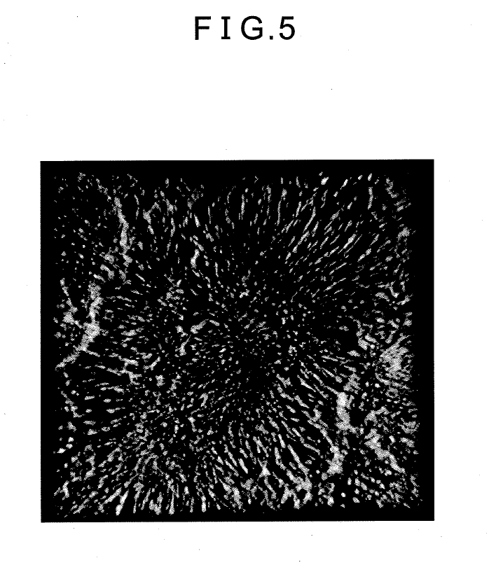

FIG. 3 shows a STEM-LAADF image of the cross-section of a superconductor film of this embodiment, while FIG. 4 shows a 3D reconstructed image of the same. For reconstruction of the 3D image, the simultaneous iterative reconstruction algorithm (SIRT) was used. For visualization, Avizo Fire 6.1 was used. Furthermore, FIG. 5 shows a 1D APCs (artificial pinning center) image prepared from the 3D reconstructed image of the ab plane cross-section.

From these results, it was confirmed that the superconductor film of the present invention is comprised of a superconductor layer inside of which columnar or rod-shaped BaZrO₃ crystals are dispersed such that they are inclined from the c-axis of the superconducting crystals and that BaZrO₃ crystals adjacent in longitudinal directions are in a skew position.

### INDUSTRIAL APPLICABILITY

According to the present invention, it is possible to obtain a previously nonexistent superconductor with a small magnetic field angle dependency of the critical current density and possible to apply this to SMES, cables, transformers, etc., so the industrial applicability is large.

### REFERENCE SIGNS LIST

10. superconductor film
11. superconductor layer (GdBa₂Cu₃O_{7-δ})
12. nanorods (rod-shaped or columnar BaZrO₃ crystals)
20. substrate

1. An oxide superconducting tape comprised of a substrate on which a GdBa₂Cu₃O_{7-δ} (δ=0 to 1) superconductor layer is formed, characterized in that,
inside of said superconductor layer, columnar or rod-shaped BaZrO₃ crystals are dispersed such that they are inclined from c-axis of the superconducting crystals and that BaZrO₃ crystals adjacent in longitudinal directions are in a skew position.
